(19) United States
(12) Patent Application Publication
(10) Pub. No.: US 2011/0037505 A1
(43) Pub. Date: Feb. 17, 2011

(54) TRANSCEIVER AND OPERATING METHOD THEREOF

(75) Inventor: Takashi KAWAMOTO, Kodaira (JP)

Correspondence Address: MATTINGLY & MALUR, P.C., 1800 DIAGONAL ROAD, SUITE 370, ALEXANDRIA, VA, 22314, US

(73) Assignee: RENESAS ELECTRONICS CORPORATION, Kanagawa (JP)

(21) Appl. No.: 12/843,926

(22) Filed: Jul. 27, 2010

(30) Foreign Application Priority Data
Aug. 17, 2009 (JP) 2009-188352

(51) Int. Cl. H03L 7/06

(52) U.S. Cl. 327/159

(57) ABSTRACT

A semiconductor chip area is reduced and the possibility of malfunction in generation of reproduction data and a reproduction clock is reduced. A transceiver comprises a clock data recovery circuit, a deserializer, a serializer, a PLL circuit, and a frequency detector. The clock data recovery circuit extracts a reproduction clock and reproduction data in response to a receive signal and a clock signal generated by the PLL circuit. The deserializer generates parallel receive data from the reproduction clock and the reproduction data, and the serializer generates a serial transmit signal from parallel transmit data and the clock signal. The detector detects a difference in frequency of the receive signal and the clock signal, and generates a frequency control signal. In response to the frequency control signal, the PLL circuit controls a cycle of the clock signal so as to reduce the difference in frequency.

### CLAIM OF PRIORITY

The present application claims priority from Japanese patent application JP 2009-188352 filed on Aug. 17, 2009, the content of which is hereby incorporated by reference into this application.

### FIELD OF THE INVENTION

The present invention relates to a transceiver and an operation method for the same, especially, to technology which is effective in reducing a semiconductor chip area and reducing possibility of malfunction in generation of reproduction data and a reproduction clock at the time of receiving a signal from a host.

### BACKGROUND OF THE INVENTION

Generally, in a device, for example, a semiconductor integrated circuit which realizes two-way communications with a host, frequency of a signal in the two-way communications between the host and the device is specified by specification. When the communication signal deviates from the specified frequency, it becomes impossible to establish the communication. Therefore, technology which adjusts the communication signal so as to have a frequency within the specification is known.

Patent Document 1 cited below describes that frequency control information outputted from a frequency control information processing unit of a receiver is transmitted to a transmitter and a frequency control unit of the transmitter controls frequency of a basic clock of the transmitter based on the frequency control information, accordingly the frequency of the basic clock of the transmitter and the frequency of a local clock of the receiver are synchronized. Patent Document 2 cited below describes that, in order to reproduce a receive clock from receive data and to synchronize a transmit clock with the receive clock, a digital PLL (Phase Locked Loop) circuit is employed, which controls a dividing ratio of a variable divider, with the use of phase difference between an output of a voltage-controlled oscillator, divided by the variable divider, and an edge detection timing detected from the receive data by an edge detector. Furthermore, Patent Document 3 cited below describes that by detecting a difference in frequency of a receive signal from a host and a transmit signal to the host by use of a frequency error detector, the frequency of the transmit signal is adjusted to the frequency of the receive signal.

On the other hand, Non-patent Document 1 cited below describes a data recovery circuit used for an optical transmission system, wherein the data recovery circuit comprises a phase comparator (PC), an up and down decision circuit (DC), a cyclic clock phase pointer (CPP), a clock interpolator (CI), and a clock selector (CS). A two-phase transmit clock signal is converted into a multi-phase clock signal by the clock interpolator (CI), and a selection clock signal is selected from the multi-phase clock signal by the clock selector (CS), in response to an output signal of the pointer (CPP). The selection clock signal and a transmission input signal of the optical transmission system are respectively supplied to a trigger input terminal and a data input terminal of three flip-flops of the phase comparator (PC). An output signal of three flip-flops is supplied to an input terminal of two exclusive OR circuits of the phase comparator (PC). An output signal of one exclusive OR circuit and an output signal of the other exclusive OR circuit are supplied to input terminals of the up and down decision circuit (DC) as an “up” request and a “down” request, respectively. An increment control signal and a decrement control signal of the up and down decision circuit (DC) are supplied to the cyclic clock phase pointer (CPP). The data recovery circuit controls timing of a data edge of the transmission input signal so that the data edge of the transmission input signal is located approximately in the center of a timing of the selection clock signal, accordingly, data recovery is enabled at a low bit error rate.

Furthermore, Non-patent Document 2 cited below describes that a spread spectrum clock generator (SSCG) for a serial ATA interface is configured by a fractional PLL circuit which toggles between two dividing ratios of a divider by an output of a ΣΔ-modulator. In Non-patent Document 2, toggling is performed between two dividing ratios (73/75) of a dual-modulus divider (DMD) by the output of the ΣΔ-modulator. In this way, the spread spectrum clock generator (SSCG) performs frequency modulation of the clock signal and reduces peak power of a fundamental wave and higher harmonics of the clock signal, in order to reduce a spurious radiation like EMI in electronic equipment. Although the total energy is the same, the peak energy can be reduced, since the clock signal is spread over a wide band, maintaining the amplitude and the waveform of a signal edge of the clock signal. In an ordinary PLL circuit in which the dividing ratio takes only an integer, a frequency resolution of the locked loop is given by a reference frequency f_{REF}. Therefore, a precise frequency resolution needs a small reference frequency f_{REF}, accordingly the loop frequency band becomes narrow. A narrow loop frequency band requires undesirably a long switching time; accordingly, suppression of a phase noise in a voltage-controlled oscillator (VCO) of the PLL circuit is insufficient, and the PLL circuit is susceptible to external noises. On the other hand, a fractional synthesizer which uses a fractional PLL circuit has been developed because of its frequency resolution more precise than a reference frequency f_{REF}. In a fractional-N divider, a dividing ratio is periodically changed from an integer N to an integer N+1, and, as a result, the average dividing ratio increases as much as a duty ratio of an (N+1) dividing compared with an N dividing. In the above, EMI is the abbreviation for Electromagnetic Interference, and ATA is the abbreviation for Advanced Technology Attachment.

(Patent Document 1) Japanese Patent Laid-open No. 2001-230750.

(Patent Document 2) Japanese Patent Laid-open No. Hei 8 (1996)-335932.

(Patent Document 3) Japanese Patent Laid-open No. 2007-135189.

(Non-patent Document 1) Yoshio Miki et al.: “A 50-mW/ch 2.5-Gb/s/ch Data Recovery Circuit for the SFI-5 Interface With Digital Eye-Tracking”, IEEE JOURNAL OF SOLID-STATE CIRCUITS, VOL. 39, NO. 4, APRIL 2004, PP. 613-621.

(Non-patent Document 2) Wei-Ta Chen et al.: “A Spread Spectrum Clock Generator for SATA-II”, 2005 IEEE International Symposium Circuits and Systems, 23-26 May 2005, PP. 2643-2646.

### SUMMARY OF THE INVENTION

In the development of a device which comprises a semiconductor integrated circuit and which uses recording media such as HDD (Hard Disk Drive), CD (Compact Disk), DVD (Digital Versatile Disk), and BD (Blue-ray Disc), versatility is required; accordingly, connectibility with various hosts is required. For a semiconductor integrated circuit for which such versatility is required, an essential subject is to be supplied to a market at an affordable price. For this reason, it is required that a semiconductor integrated circuit should be mass-produced with a small chip area.

In advance of the present invention, the present inventors have been engaged in research and development of a device which comprises a semiconductor integrated circuit and which uses recording media such as HDD, CD, DVD, and BD, capable of coupling with various hosts.

In the research and development of the device, a serial ATA interface using a spread spectrum clock generator (SSCG) has been adopted in coupling with a host, in order to reduce a spurious radiation.

In the research and development of the device, adoption of a data recovery circuit described in Non-patent Document 1 cited above has been examined, in order to reproduce a frequency-diffused clock and a transmit signal with a high accuracy, in the state where a clock signal frequency of a receive signal from a host is spread by the serial ATA interface which uses the spread spectrum clock generator (SSCG).

FIG. 1 illustrates a configuration of a device which has been examined by the present inventors in advance of the present invention. The device comprises a semiconductor integrated circuit and uses a recording medium.

The following explains in detail a semiconductor integrated circuit 7 configuring the device illustrated in FIG. 1.

Generally, there is a serial ATA interface unit, for example, as a standard interface for coupling memory media (peripheral device) such as an optical disk device and a hard disk device, to computers such as a personal computer. By using the serial ATA, various kinds of memory media can be coupled to a computer under a command and control software with compatibility. In the device illustrated in FIG. 1, an optical disk device is adopted as the memory medium, and this peripheral device is coupled to a host computer by a serial ATAPI. Here, ATAPI is the abbreviation for Advanced Technology Attachment Peripheral Interface.

The optical disk device illustrated in FIG. 1 comprises an optical disk 5, an optical pickup 6, a semiconductor integrated circuit 7, and a crystal oscillator 3. The optical disk device is coupled with a host computer (HOST) 2 with a serial ATAPI system.

The optical pickup 6 irradiates the optical disk 5 with an optical beam, and performs reading and writing of data. The semiconductor integrated circuit 7 comprises a recording/reproduction unit (READ/WRITE) 8 which performs data writing and data reading of the optical pickup 6, and an interface unit (ATAPI) 1 which performs outputting and inputting data of the recording/reproduction unit 8 to the host computer (HOST) 2.

The interface unit (ATAPI) 1 comprises a serializer (SER) 14, a first PLL circuit 16, a second PLL circuit (PLL) 13, a deserializer (DES) 15, and a clock data recovery circuit (CDR) 11.

In data reading from the optical disk as a peripheral device, the serializer (SER) 14 serving as a parallel-to-serial converter converts parallel transmit data from the recording/reproduction unit 8 into a serial transmit signal which is synchronized with a clock supplied by the second PLL circuit (PLL) 13, and outputs the converted signal to the host computer 2. Namely, in the data reading of the optical disk 5, the serializer (SER) 14 of the interface unit (ATAPI) 1 converts the parallel transmit data from the recording/reproduction unit 8 into the serial transmit signal TX which is synchronized with the clock CLK2 supplied by the second PLL circuit (PLL) 13, and outputs the serial transmit signal TX to the host computer 2. Since the second PLL circuit (PLL) 13 configures a spread spectrum clock generator (SSCG) by use of a fractional PLL circuit comprising a ΣΔ-modulator as described in Non-patent Document 2 cited above, it becomes possible to reduce spurious radiation caused by the serial transmit signal TX in the present case.

On the other hand, in data writing to the optical disk as a peripheral device, the clock data recovery circuit (CDR) 11 receives a receive signal RX from the host computer 2, and generates serial reproduction data DATA and a reproduction clock CLK, in response to a clock CLK1 supplied by the first PLL circuit 16, and outputs them to the deserializer (DES) 15. The deserializer (DES) 15 serving as a serial-to-parallel converter generates parallel receive data from the serial reproduction data and the reproduction clock, and the data writing to the optical disk is performed. Namely, in the data writing to the optical disk 5, the clock data recovery circuit (CDR) 11 of the interface unit (ATAPI) 1 receives the receive signal RX from the host computer 2, generates the serial reproduction data DATA and the reproduction clock CLK in response to the clock CLK1 supplied by the first PLL circuit 16, and outputs them to the deserializer (DES) 15. The deserializer (DES) 15 generates the parallel receive data from the serial reproduction data DATA and the reproduction clock CLK, and outputs the parallel receive data generated to the recording/reproduction unit 8, and the data writing to the optical disk 5 is performed. The reproduction clock CLK reproduced from the clock data recovery circuit (CDR) 11 is supplied to an input terminal of the first PLL circuit 16 as a reference frequency signal. As the result, with the use of the serial ATA interface using the spread spectrum, frequency of the clock CLK1 generated by the first PLL circuit 16 can be changed, following change of the frequency of the clock signal of the receive signal RX from the host computer 2 and the frequency of the reproduction clock CLK. Accordingly, even in the state where the clock frequency changes due to the serial ATA interface using the spread spectrum, it is possible for the clock data recovery circuit (CDR) 11 of the interface unit (ATAPI) 1 to generate the serial reproduction data DATA and the reproduction clock CLK.

However, the present inventors have clarified a problem that the semiconductor integrated circuit 7 illustrated in FIG. 1 has a large semiconductor chip area, because the semiconductor integrated circuit 7 comprises the first PLL circuit 16 and the second PLL circuit (PLL) 13. Especially, a loop filter (LP) of a PLL circuit comprises a capacitive element and a resistive element which occupy a large chip area, and a voltage-controlled oscillator (VCO) of the PLL circuit comprises a CMOS inverter chain with multi stages. Therefore, the semiconductor integrated circuit 7 illustrated in FIG. 1 has a large chip occupied area.

Accordingly, in advance of the present invention, the present inventors have examined sharing of a single PLL circuit by the first PLL circuit 16 and the second PLL circuit (PLL) 13, in order to reduce the semiconductor chip area of the semiconductor integrated circuit 7 illustrated in FIG. 1, which has been examined by the present inventors in advance of the present invention.

In the present sharing, in response to a clock which the single shared PLL circuit generates, the serializer (SER) 14 converts parallel transmit data from recording/reproduction unit 8 into serial transmit data TX, and outputs them to the host computer 2. In the case, change of frequency of the serial transmit data TX and the clock generated by the single shared PLL circuit is determined by a spread spectrum on the side of the device.

On the other hand, in the present sharing, in response to a clock which the single shared PLL circuit generates, the clock data recovery circuit (CDR) 11 receives a receive signal RX from the host computer 2, generates serial reproduction data DATA and a reproduction clock CLK, and outputs them to the deserializer (DES) 15. However, in the case, change of frequency of the receive signal RX and the reproduction clock CLK is determined by a spread spectrum on the side of the host.

On the other hand, in a serial ATA interface, as transmitting for signals between a host and a device, the specification allows transmitting of only a receive signal RX from the host and a transmit signal TX from the device, but prohibits transmitting of any other signals. Accordingly, a receive clock for reception of the receive signal RX from the host in the device and a transmit clock for transmission of the transmit signal TX to the host in the device are in an asynchronous relation. As a result, by the sharing described above, the clock frequency of the serializer (SER) 14 which has frequency determined by the spread spectrum on the side of the device and the clock frequency of the clock data recovery circuit (CDR) 11 which has frequency determined by the spread spectrum on the side of the host disagree with each other. The examination by the present inventors has clarified a problem that, when the difference of the frequencies in the case becomes conspicuous, normal operation will become difficult in generation of the serial reproduction data DATA and the reproduction clock CLK through reception of the receive signal RX from the host computer 2 in the clock data recovery circuit (CDR) 11.

The present invention has been made as a result of the examination described above by the present inventors in advance of the present invention.

Therefore, the purpose of the present invention lies in reducing a semiconductor chip area of a semiconductor integrated circuit which is comprised by a device capable of coupling with a host, and also lies in reducing possibility of malfunction in generation of reproduction data and a reproduction clock at the time of receiving a receive signal from a host.

The above and other purposes and new features will become clear from description of the specification and the accompanying drawings of the present invention.

The followings explain briefly typical inventions to be disclosed by the present application.

That is, a transceiver (7) according to a typical embodiment of the present invention comprises a clock data recovery circuit (11), a deserializer (15), a serializer (14), a PLL circuit (13), and a frequency detector (12).

The clock data recovery circuit (11) extracts a reproduction clock (CLK) and reproduction data (DATA), in response to a receive signal (RX) and a clock signal (TXCLK) generated by the PLL circuit (13).

The deserializer (15) serving as a serial-to-parallel converter generates parallel receive data (DT) from the reproduction clock (CLK) and the reproduction data (DATA).

The serializer (14) serving as a parallel-to-serial converter generates a serial transmit signal (TX) from parallel transmit data (DR) and the clock signal (TXCLK) generated by the PLL circuit (13).

The frequency detector (12) generates a frequency control signal (FCS) to be supplied to the PLL circuit (13), by detecting a difference in frequency of the receive signal (RX) and the clock signal (TXCLK).

The PLL circuit (13) controls a cycle of the clock signal (TXCLK) so as to reduce the difference in frequency of the receive signal (RX) and the clock signal (TXCLK) in response to the frequency control signal (FCS) (refer to FIG. 2 and FIG. 12).

The following explains briefly an effect obtained by the typical inventions to be disclosed in the present application.

That is, according to the present invention, it is possible to reduce a semiconductor chip area and also possible to reduce possibility of malfunction in generation of reproduction data and a reproduction clock at the time of receiving a receive signal from a host.

### BRIEF DESCRIPTION OF THE DRAWINGS

FIG. 1 is a drawing illustrating a configuration of a device which has been examined by the present inventors in advance of the present invention. The device comprises a semiconductor integrated circuit and uses a recording medium;

FIG. 2 is a drawing illustrating a configuration of a communication system comprising a transceiver according to Embodiment 1 of the present invention;

FIG. 3 is a drawing illustrating a configuration of a clock data recovery circuit (CDR) 11 of a device 1 configured as a transceiver with a transmitting/receiving function illustrated in FIG. 2;

FIG. 4A is a timing chart illustrating timing relationship between signals, for explaining operation of the clock data recovery circuit (CDR) 11 illustrated in FIG. 3;

FIG. 4B is a drawing illustrating relation between a selection clock output signal and a jitter component, for explaining operation of the clock data recovery circuit (CDR) 11 illustrated in FIG. 3;

FIG. 5 is a drawing illustrating a configuration of a frequency error detector (CNT) 12 of the device 1 configured as the transceiver with a transmitting/receiving function illustrated in FIG. 2;

FIG. 6 is a drawing illustrating a configuration of a frequency error detection regulator (DDC) 123 of the frequency error detector (CNT) 12 illustrated in FIG. 5;

FIG. 7 is a drawing illustrating a configuration of a PLL circuit (PLL) 13 of the device 1 configured as the transceiver with a transmitting/receiving function illustrated in FIG. 2;

FIG. 8 is a drawing illustrating a configuration of a voltage-controlled oscillator (VCO) 134 of the PLL circuit (PLL) 13 illustrated in FIG. 7;

FIG. 9A is a drawing illustrating a configuration of a voltage-to-current converter (VIC) 1341 of the voltage-controlled oscillator (VCO) 134 illustrated in FIG. 8;

FIG. 9B is a drawing illustrating a configuration of a delay circuit 1342 which corresponds to each of four stages of delay circuits 1342A, 1342B, 1342C, and 1342D of the voltage-controlled oscillator (VCO) 134 illustrated in FIG. 8;

FIG. 10A is a drawing illustrating a configuration of a waveform generation unit 138 of the PLL circuit (PLL) 13 illustrated in FIG. 7;

FIG. 10B is a drawing illustrating an operating waveform of the waveform generation unit 138 of the PLL circuit (PLL) 13 illustrated in FIG. 7;

FIG. 11 is a drawing explaining a frequency control operation of a transmit clock TXCLK of a communication system comprising the transceiver according to Embodiment 1 of the present invention, explained in FIG. 2 through FIG. 10B;

FIG. 12 is a drawing illustrating a configuration of a communication system comprising a transceiver according to Embodiment 2 of the present invention;

FIG. 13 is a drawing illustrating a configuration of a PLL circuit (PLL) 13 of the device 1 configured as the transceiver according to Embodiment 2 of the present invention 2, illustrated in FIG. 12;

FIG. 14 is a drawing illustrating a configuration of a frequency error detector (CNT) 12 of the device 1 configured as the transceiver with a transmitting/receiving function according to Embodiment 2 of the present invention 2, illustrated in FIG. 12;

FIG. 15 is a drawing illustrating a configuration of a frequency error detection regulator (DDC) 123 of the frequency error detector (CNT) 12 illustrated in FIG. 14;

FIG. 16 is a drawing explaining a maximum frequency (UF), an average frequency (AF), and a minimum frequency (DF) of the frequency of a single-phase transmit clock signal TXCLK and a receive signal RX, which are measured by a first and a second frequency detector (FD) 1231A and 1231B of the frequency error detection regulator (DDC) 123 illustrated in FIG. 15;

FIG. 17A is a drawing illustrating a configuration of a waveform generation unit 138 of the PLL circuit (PLL) 13 illustrated in FIG. 13;

FIG. 17B is a drawing illustrating an operating waveform of a waveform generation unit 138 of the PLL circuit (PLL) 13 illustrated in FIG. 13, specifically illustrating relation of a modulation cycle adjustment signal MN, a dividing feedback signal fm, and a waveform signal FWAVE;

FIG. 17C is a drawing illustrating an operating waveform of the waveform generation unit 138 of the PLL circuit (PLL) 13 illustrated in FIG. 13, specifically illustrating relation of a degree-of-modulation adjustment signal MT, a dividing feedback signal fm, and a waveform signal FWAVE;

FIG. 18 is a drawing explaining a frequency control operation of a transmit clock TXCLK of a communication system comprising the transceiver according to Embodiment 2 of the present invention, explained in FIG. 12 through FIG. 17C; and

FIG. 19 is a drawing illustrating a configuration of a communication system with a device as a transceiver comprising a semiconductor integrated circuit according to Embodiment 3 of the present invention.

### DETAILED DESCRIPTION OF THE PREFERRED EMBODIMENTS

### 1. Summary of the Preferred Embodiments

First, an outline is explained about typical embodiments of the invention disclosed in the present application. A reference symbol in parentheses referring to a component of the drawing in the outline explanation about the typical embodiment only illustrates what is included in the concept of the component to which the reference symbol is attached.

<1> A transceiver (7) according to a typical embodiment of the present invention comprises a clock data recovery circuit (11), a deserializer (15), a serializer (14), a PLL circuit (13), and a frequency detector (12).

The clock data recovery circuit (11) extracts a reproduction clock (CLK) and reproduction data (DATA), in response to a receive signal (RX) and a clock signal (TXCLK) generated by the PLL circuit (13).

The deserializer (15) serving as a serial-to-parallel converter generates parallel receive data (DT) from the reproduction clock (CLK) and the reproduction data (DATA).

The serializer (14) serving as a parallel-to-serial converter generates a serial transmit signal (TX) from parallel transmit data (DR) and the clock signal (TXCLK) generated by the PLL circuit (13).

The frequency detector (12) generates a frequency control signal (FCS) to be supplied to the PLL circuit (13), by detecting a difference in frequency of the receive signal (RX) and the clock signal (TXCLK).

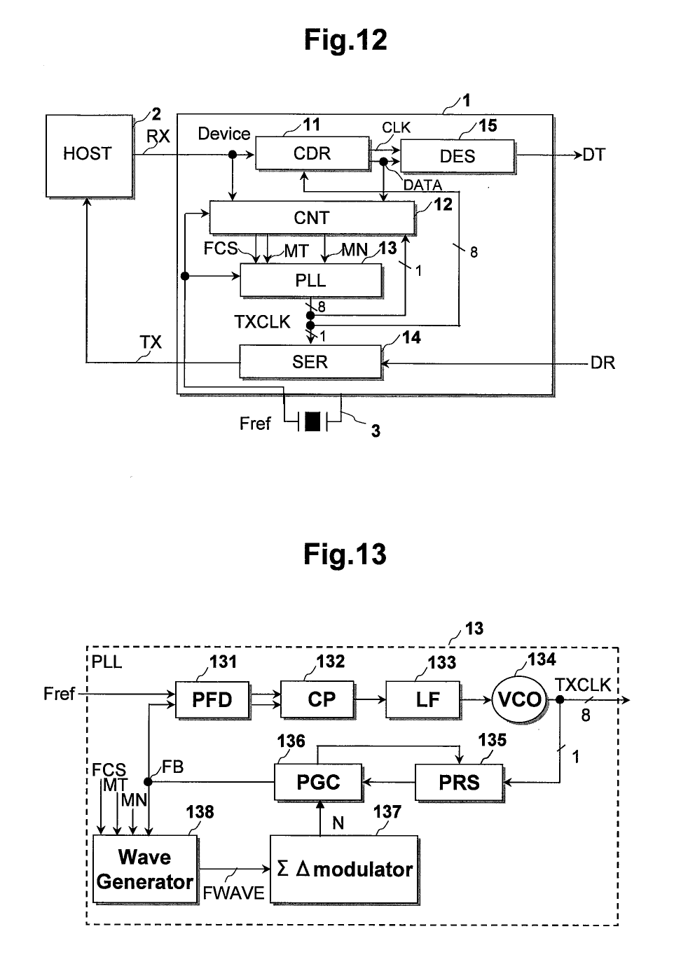

The PLL circuit (13) controls a cycle of the clock signal (TXCLK) so as to reduce the difference in frequency of the receive signal (RX) and the clock signal (TXCLK) in response to the frequency control signal (FCS) (Refer to FIG. 2 and FIG. 12).

According to the embodiment, it is possible to reduce a semiconductor chip area and also possible to reduce possibility of malfunction in generation of reproduction data and a reproduction clock at the time of receiving a receive signal from a host.

In a transceiver (7) according to a preferred embodiment, the PLL circuit (13) comprises a waveform generator (138), a ΣΔ-modulator (137), and a variable divider (136).

In response to a waveform signal (FWAVE) generated by the waveform generator (138), the ΣΔ-modulator (137) controls a number of average dividing (N) of the variable divider (136) to a value below a decimal point; therefore, the PLL circuit (13) configures a spread spectrum clock generator (SSCG) (refer to FIG. 7 and FIG. 13).

According to the preferred embodiment, it becomes possible to reduce spurious radiation at the time of generating a serial transmit signal (TX).

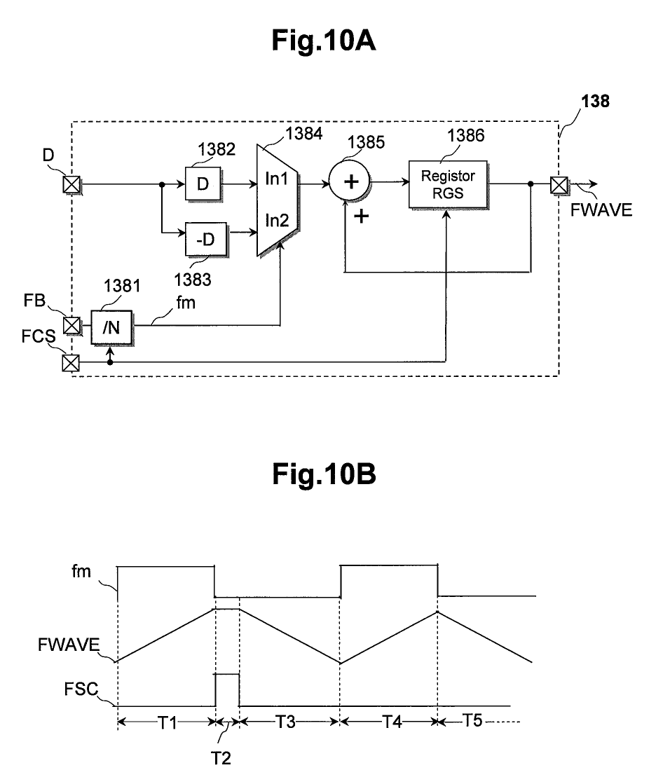

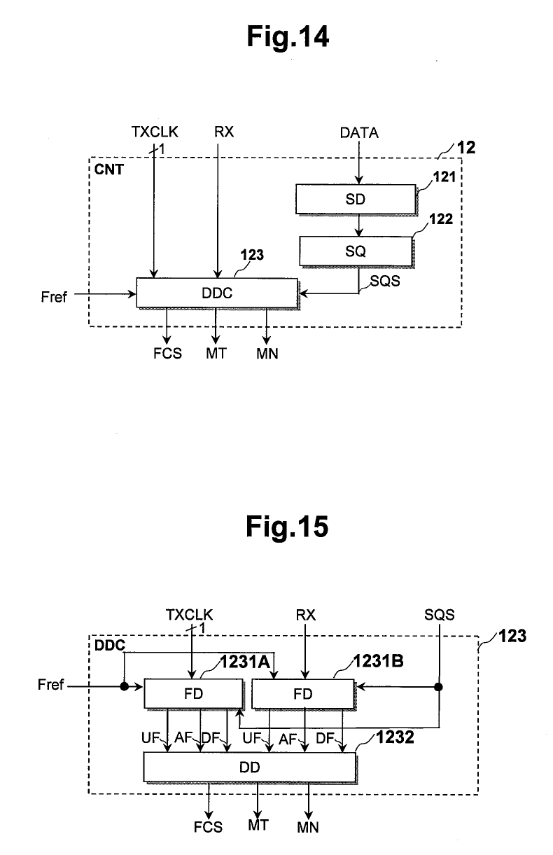

In a transceiver (7) according to more preferred embodiment, a phase of the clock signal (TXCLK) generated by the PLL circuit (13) is controlled by supplying the frequency control signal (FCS) generated by the frequency detector (12) to the waveform generator (138) of the PLL circuit (13) (refer to FIG. 10A, FIG. 10B, FIG. 14, and FIG. 15).

In a transceiver (7) according to another preferred embodiment, by detecting the difference in frequency of the receive signal (RX) and the clock signal (TXCLK), the frequency detector (12) generates a modulation cycle adjustment signal (MN) and a degree-of-modulation adjustment signal (MT) which are supplied to the PLL circuit (13) (refer to FIG. 14 and FIG. 15).

In response to the modulation cycle adjustment signal (MN) and the degree-of-modulation adjustment signal (MT), the PLL circuit (13) controls the cycle and degree of modulation of the clock signal (TXCLK) so as to reduce the difference in frequency of the receive signal (RX) and the clock signal (TXCLK) (refer to FIG. 17A-FIG. 17C).

In a transceiver (7) according to a specific embodiment, the clock data recovery circuit (11) comprises a phase comparator (111), an integrator (112), a phase selection unit (113), and a clock selection unit (114).

The clock selection unit (114) is supplied with multiphase clock signals (TXCLK0-TXCLK7) generated by the PLL circuit (13) and a pointer value (P) generated by the phase selection unit (113), and the clock selection unit (114) generates plural selection clock output signals (CLK0-CLK2) from the multiphase clock signals, in response to the pointer value (P).

The phase comparator (111) is supplied with the receive signal (RX) and the plural selection clock output signals (CLK0-CLK2) generated by the clock selection unit (114), and the phase comparator (111) generates an early phase signal (EARLY) and a late phase signal (LATE), in response to relation between a phase of the receive signal (RX) and plural phases of the plural selection clock output signals (CLK0-CLK2).

The integrator (112) is supplied with the early phase signal (EARLY) and the late phase signal (LATE) generated by the phase comparator (111), and generates an “up” signal (UP) and a “down” signal (DN).

The clock selection unit (114) is supplied with the “up” signal (UP) and the “down” signal (DN) generated by the integrator (112), and a value of the pointer value (P) generated by the clock selection unit (114) is set up (refer to FIG. 4A and FIG. 4B).

In a transceiver (7) according to another specific embodiment, the clock data recovery circuit (11), the deserializer (15), the serializer (14), the PLL circuit (13), and the frequency detector (12) are formed in a semiconductor integrated circuit (1) (refer to FIG. 2 and FIG. 12).

In a transceiver (7) according to most specific embodiment, the waveform signal (FWAVE) generated by the waveform generator (138) of the PLL circuit (13) is a triangular-wave signal (refer to FIG. 10A, FIG. 10B, FIG. 17A, FIG. 17B, and FIG. 17C).

<2> A typical embodiment of another viewpoint of the present invention presents an operation method of a transceiver (7) comprising a clock data recovery circuit (11), a deserializer (15), a serializer (14), a PLL circuit (13), and a frequency detector (12).

The clock data recovery circuit (11) extracts a reproduction clock (CLK) and reproduction data (DATA), in response to a receive signal (RX) and a clock signal (TXCLK) generated by the PLL circuit (13).

The deserializer (15) serving as a serial-to-parallel converter generates parallel receive data (DT) from the reproduction clock (CLK) and the reproduction data (DATA).

The serializer (14) serving as a parallel-to-serial converter generates a serial transmit signal (TX) from parallel transmit data (DR) and the clock signal (TXCLK) generated by the PLL circuit (13).

The frequency detector (12) generates a frequency control signal (FCS) to be supplied to the PLL circuit (13), by detecting a difference in frequency of the receive signal (RX) and the clock signal (TXCLK).

The PLL circuit (13) controls a cycle of the clock signal (TXCLK) so as to reduce the difference in frequency of the receive signal (RX) and the clock signal (TXCLK) in response to the frequency control signal (FCS) (Refer to FIG. 2 and FIG. 12).

According to the embodiment, it is possible to reduce a semiconductor chip area and also possible to reduce possibility of malfunction in generation of reproduction data and a reproduction clock at the time of receiving a receive signal from a host.

### 2. Further Detailed Description of the Preferred Embodiments

Next, embodiments are explained further in full detail. In the entire drawings for explaining the preferred embodiments of the present invention, the same symbol is attached to a component which has the same function, and the repeated explanation thereof is omitted.

### Embodiment 1

### Communication System

FIG. 2 illustrates a configuration of a communication system comprising the transceiver according to Embodiment 1 of the present invention.

A communication system illustrated in FIG. 2 comprises a device 1 and a host 2. The device 1 is configured as a transceiver which has a transmitting/receiving function. The host 2 is also configured as a transceiver which has a transmitting/receiving function. Accordingly, two-way communications between the device 1 and the host 2 are possible. That is, in the communication system illustrated in FIG. 2, the host 2 outputs a receive signal RX to the device 1, and receives a transmit signal TX from the device 1. The device 1 receives the receive signal RX from the host 2 and outputs receive data DT, and receives transmit data DR and transmits the transmit signal TX to the host 2.

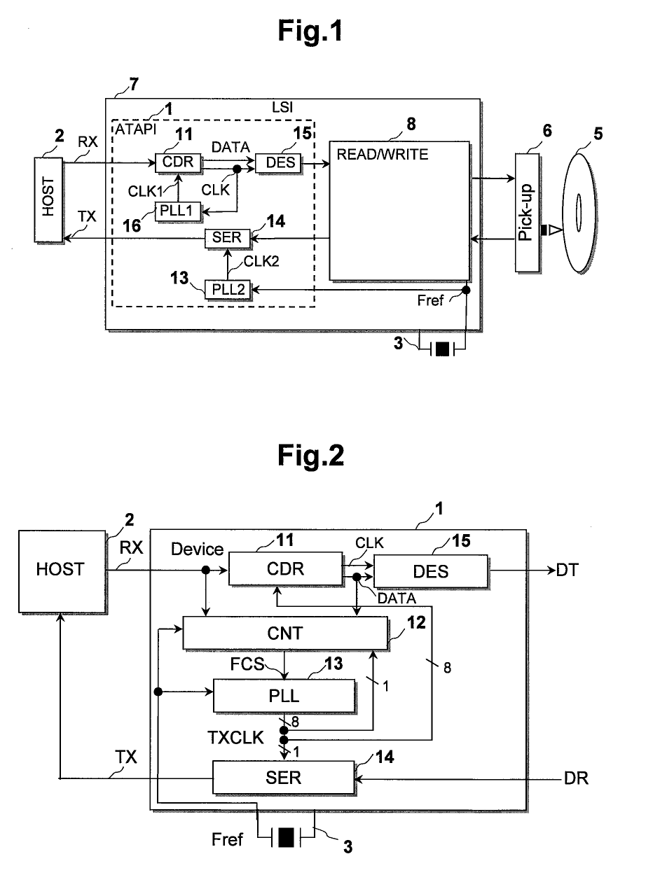

The device 1 of the communication system illustrated in FIG. 2 corresponds to the interface unit (ATAPI) 1 illustrated in FIG. 1. The receive data DT from the device 1 is written in a recording medium 5, such as HDD, via the recording/reproduction unit 8 and the pickup 6 which are illustrated in FIG. 1. On the other hand, written-in data of the recording medium 5 is read via the pickup 6 and the recording/reproduction unit 8, and is transmitted to the device 1 as the transmit data DR. A reference signal generation source 3 which supplies a reference signal Fref is coupled to the device 1, and another reference signal generation source (not shown in FIG. 2) which supplies another reference signal is coupled to the host 2.

The device 1 illustrated in FIG. 2 is a transceiver comprised of a semiconductor integrated circuit, and comprises a clock data recovery circuit (CDR) 11, a serializer (SER) 14, and a deserializer (DES) 15, as is the case with the interface unit (ATAPI) 1 illustrated in FIG. 1. The first PLL circuit 16 and the second PLL circuit (PLL) 13 of the interface unit (ATAPI) 1 illustrated in FIG. 1 share a single PLL circuit (PLL) 13 in the device 1 illustrated in FIG. 2. Especially, a frequency error detector (CNT) 12, which is not included in the interface unit (ATAPI) 1 of FIG. 1, is added to the device 1 illustrated in FIG. 2.

Almost same as is the case with the data recovery circuit described in Non-patent Document 1 cited above, the clock data recovery circuit (CDR) 11 extracts a reproduction clock CLK and reproduction data DATA and outputs them to the deserializer (DES) 15, in response to a receive signal RX which is transmitted from the host 2 and received by the device 1, and in response to an eight-phase clock signal TXCLK which is generated by the PLL circuit (PLL) 13. Then, the deserializer (DES) 15 serving as a serial-to-parallel converter generates parallel receive data DT from the serial reproduction data DATA and the reproduction clock CLK, and data writing to the recording medium 5 is performed.

In data reading from the recording medium 5, the serializer (SER) 14 serving as a parallel-to-serial converter converts the parallel transmit data DR from the recording/reproduction unit 8 into the serial transmit signal TX which is synchronized with the single-phase clock signal TXCLK supplied by the PLL circuit (PLL) 13. Then the serial transmit signal TX is outputted to the host 2. In the case, the PLL circuit (PLL) 13 configures a spread spectrum clock generator (SSCG) with the use of a fractional PLL circuit which comprises a ΣΔ-modulator as described in Non-patent Document 2. Therefore, it becomes possible to reduce spurious radiation caused by the serial transmit signal TX.

To the frequency error detector (CNT) 12, the following signals are supplied: that is, the receive signal RX from the host 2, the reproduction data DATA from the clock data recovery circuit (CDR) 11, the reference signal Fref from the reference signal generation source 3, and the single-phase transmit clock TXCLK from the PLL circuit (PLL) 13 are supplied. Accordingly, when the frequency error detector (CNT) 12 detects a great difference in frequency of the receive signal RX and the transmit clock TXCLK, the frequency error detector (CNT) 12 outputs a frequency control signal FCS to the PLL circuit (PLL) 13. Then, responding to the frequency control signal FCS, the PLL circuit (PLL) 13 operates so as to reduce the difference in frequency of the receive signal RX and the transmit clock TXCLK, by controlling the cycle of the eight-phase clock signal TXCLK supplied to the clock data recovery circuit (CDR) 11.

The following explains a configuration and operation of internal circuits, such as the clock data recovery circuit (CDR) 11, the frequency error detector (CNT) 12, and the PLL circuit (PLL) 13, which are comprised in the communication system illustrated in FIG. 2.

<<A Configuration of the Clock Data Recovery Circuit>>

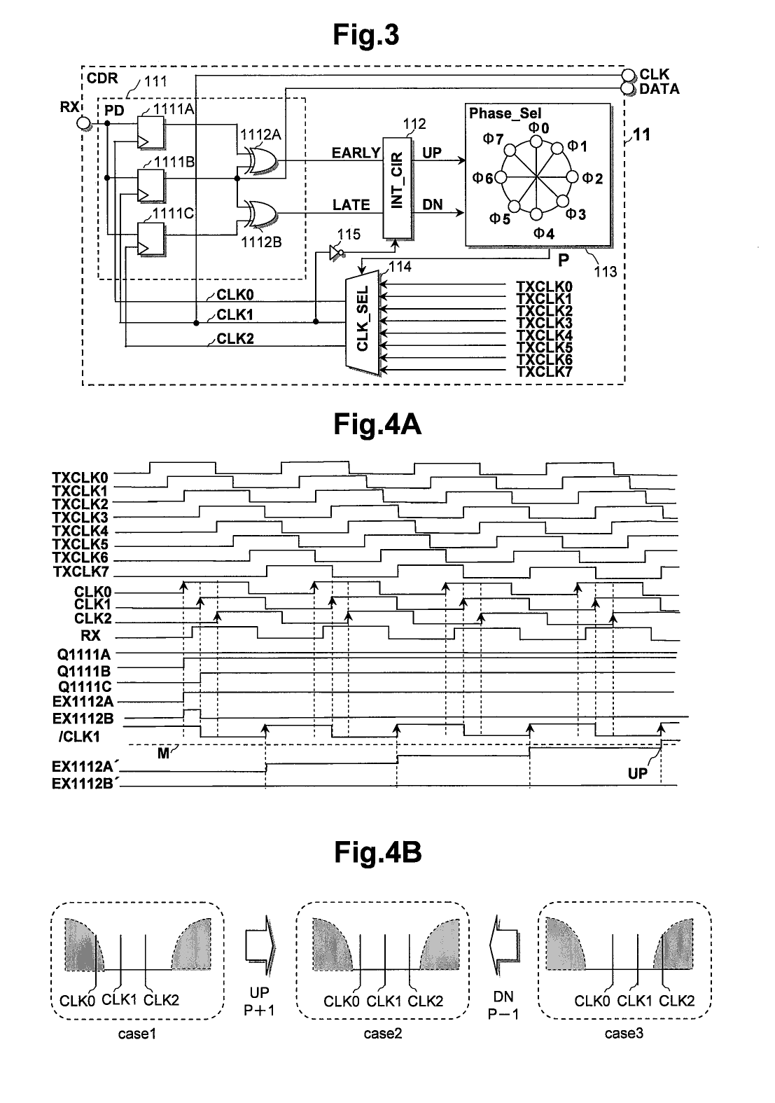

FIG. 3 illustrates a configuration of the clock data recovery circuit (CDR) 11 of the device 1 configured as a transceiver with a transmitting/receiving function illustrated in FIG. 2.

A fundamental configuration of the clock data recovery circuit (CDR) 11 illustrated in FIG. 3 is similar to the configuration of a data recovery circuit described in Non-patent Document 1 cited above. The clock data recovery circuit (CDR) 11 illustrated in FIG. 3 comprises a phase comparator (PD) 111, an integrator (INT_CIR) 112, a phase selection unit (Phase_Sel) 113, a clock selection unit (CLK_SEL) 114, and an inverter 115.

A receive signal RX outputted by the host 2 is supplied in common to data input terminals of three flip-flops 1111A, 1111B, and 1111C of the phase comparator (PD) 111. On the other hand, three selection clock output signals CLK0, CLK1, and CLK2 outputted from the clock selection unit (CLK_SEL) 114 are supplied to trigger input terminals of three flip-flops 1111A, 1111B, and 1111C, respectively. An output signal of the first flip-flop 1111A and an output signal of the second flip-flop 1111B of the phase comparator (PD) 111 are supplied to an input terminal of a first exclusive OR circuit 1112A. On the other hand, The output signal of the second flip-flop 1111B and an output signal of the third flip-flop 1111C of the phase comparator (PD) 111 are supplied to an input terminal of a second exclusive OR circuit 1112B.

An output signal EARLY of the first exclusive OR circuit 1112A and an output signal LATE of the second exclusive OR circuit 1112B of the phase comparator (PD) 111 are supplied to data input terminals of the integrator (INT_CIR) 112. On the other hand, the second selection clock output signal CLK1 from the clock selection unit (CLK_SEL) 114 is supplied to an input terminal of the inverter 115, and an output signal of the inverter 115 is supplied to a trigger input terminal of the integrator (INT_CIR) 112.

An “up” output signal UP and a “down” output signal DN of the integrator (INT_CIR) 112 are supplied to input terminals of the phase selection unit (Phase_Sel) 113, and a pointer output signal P of the phase selection unit (Phase_Sel) 113 is supplied to a selection input terminal of the clock selection unit (CLK_SEL) 114. Eight-phase clock signals TXCLK0, TXCLK1, TXCLK2, TXCLK3, TXCLK4, TXCLK5, TXCLK6, and TXCLK7, which are generated by the PLL circuit (PLL) 13, are supplied to eight data input terminals of the clock selection unit (CLK_SEL) 114. According to a value of the pointer output signal P supplied to the selection input terminal of the clock selection unit (CLK_SEL) 114, three clock signals are generated by the clock selection unit (CLK_SEL) 114 from the eight-phase clock signals TXCLK0-TXCLK7, as the first selection clock output signal CLK0, the second selection clock output signal CLK1, and the third selection clock output signal CLK2.

In the clock data recovery circuit (CDR) 11 illustrated in FIG. 3, an output signal generated from the output terminal of the second flip-flop 1111B is outputted to the deserializer (DES) 15 and the frequency error detector (CNT) 12, as the reproduction data DATA. On the other hand, the second selection clock output signal CLK1 generated by the clock selection unit (CLK_SEL) 114 is outputted to the deserializer (DES) 15 as the reproduction clock CLK.

<<Operation of the Clock Data Recovery Circuit>>

FIG. 4A and FIG. 4B explain operation of the clock data recovery circuit (CDR) 11 illustrated in FIG. 3. FIG. 4A is a timing chart illustrating timing relationship among signals. FIG. 4B illustrates relation between a selection clock output signal and a jitter component.

The upper part of FIG. 4A illustrates the eight-phase clock signals TXCLK0, TXCLK1, TXCLK2, TXCLK3, TXCLK4, TXCLK5, TXCLK6, and TXCLK7, which are generated by the PLL circuit (PLL) 13 and supplied to the eight data input terminals of the clock selection unit (CLK_SEL) 114.

The central part of FIG. 4A illustrates the receive signal RX from the host 2, and the first selection clock output signal CLK0, the second selection clock output signal CLK1, and the third selection clock output signal CLK2, which are generated by the clock selection unit (CLK_SEL) 114. In the present example, the third clock signal TXCLK2, the fourth clock signal TXCLK3, and the fifth clock signal TXCLK4, which are selected from the eight-phase clock signals TXCLK0-TXCLK7, are outputted from the clock selection unit (CLK_SEL) 114 as the first selection clock output signal CLK0, the second selection clock output signal CLK1, and the third selection clock output signal CLK2, respectively. Also in the present example, a rising edge of the receive signal RX from the host 2 is located in timing between a rising edge of the first selection clock output signal CLK0 and a rising edge of the second selection clock output signal CLK1.

The lower part of FIG. 4A illustrates output signals Q1111A, Q1111B, and Q1111C of three flip-flops 1111A, 1111B, and 1111C of the phase comparator (PD) 111, an output signal EX1112A (output signal EARLY) and EX1112B (output signal LATE) of the exclusive OR circuits 1112A and 1112B of the phase comparator (PD) 111, and an inverted signal /CLK1 of the second selection clock output signal CLK1 as an output signal of inverter 115. The integrator (INT_CIR) 112 of the clock data recovery circuit (CDR) 11 of FIG. 3 integrates sequentially level of the output signal EX1112A (output signal EARLY) and EX1112B (output signal LATE) of the exclusive OR circuits 1112A and 1112B, at a rising edge of the inverted signal /CLK1.

The lowermost part of FIG. 4A illustrates a waveform of an integrated value EX1112A′ of the output signal EX1112A (output signal EARLY) of the first exclusive OR circuit 1112A, and a waveform of an integrated value EX1112B′ of the output signal EX1112B (output signal LATE) of the second exclusive OR circuit 1112B.

Since the output signal EX1112B (output signal LATE) of the second exclusive OR circuit 1112B is at a low level (ground potential) at the timing of the rising edge of the inverted signal/CLK1, the integrated value EX1112B′ of the output signal EX1112B (output signal LATE) of the second exclusive OR circuit 1112B also becomes a low level (ground potential). Since the output signal EX1112A (output signal EARLY) of the first exclusive OR circuit 1112A is at a high level to the contrary, the integrated value EX1112A′ of the output signal EX1112A (output signal EARLY) of the first exclusive OR circuit 1112A increases stepwise, as illustrated in the lowermost part of FIG. 4A.

The integrator (INT_CIR) 112 of the clock data recovery circuit (CDR) 11 illustrated in FIG. 3 detects a difference between the level of the integrated value EX1112A′ of the output signal EX1112A (output signal EARLY) of the first exclusive OR circuit 1112A and the level of the integrated value EX1112B′ of the output signal EX1112B (output signal LATE) of the second exclusive OR circuit 1112B. When the level of the integrated value EX1112A′ is higher than an additional value of the level of the integrated value EX1112B′ and a predetermined value M, the integrator (INT_CIR) 112 generates an “up” output signal UP. When the level of the integrated value EX1112B′ is higher than an additional value of the level of the integrated value EX1112A′ and the predetermined value M, the integrator (INT_CIR) 112 generates a “down” output signal DN.

In the clock data recovery circuit (CDR) 11 illustrated in FIG. 3, the pointer value P of the phase selection unit (Phase_Sel) 11 is incremented by one, in response to the “up” output signal UP generated by the integrator (INT_CIR) 112. The phase selection unit (Phase_Sel) 11 has eight pointers φ0, φ1, φ2, φ3, φ4, φ5, φ6, and φ7, corresponding to the eight-phase clock signals TXCLK0-TXCLK7. The initial value of the pointer is arbitrarily set as one of the eight pointers φ0-φ7. The value of the pointer shifts clockwise from the initial value in response to the “up” output signal UP, while the value of the pointer shifts counter clockwise from the initial value in response to the “down” output signal DN.

In response to the event that the pointer value P of the phase selection unit (Phase_Sel) 11 is incremented by one, the fourth clock signal TXCLK3, the fifth clock signal TXCLK4, and the sixth clock signal TXCLK5 which are selected from the eight-phase clock signals TXCLK0-TXCLK7, are outputted from the clock selection unit (CLK_SEL) 114, as the first selection clock output signal CLK0, the second selection clock output signal CLK1, and the third selection clock output signal CLK2, respectively.

The left-hand drawing of FIG. 4B illustrates a condition case1 before the integrator (INT_CIR) 112 generates an “up” output signal UP. In the condition case1, it is understood that the first selection clock output signal CLK0 outputted by the clock selection unit (CLK_SEL) 114 is buried in a left-hand side jitter component. In such a condition case1, it is difficult for the clock data recovery circuit (CDR) 11 illustrated in FIG. 3 to recover reproduction data DATA at a low bit error rate. The condition case1 illustrated in the left-hand drawing of FIG. 4B corresponds to the condition where the third clock signal TXCLK2, the fourth clock signal TXCLK3, and the fifth clock signal TXCLK4, which are selected from the eight-phase clock signals TXCLK0-TXCLK7, are outputted from the clock selection unit (CLK_SEL) 114 as the first selection clock output signal CLK0, the second selection clock output signal CLK1, and the third selection clock output signal CLK2, respectively, and where the rising edge of the receive signal RX from the host 2 is located in timing between the rising edge of the first selection clock output signal CLK0 and the rising edge of the second selection clock output signal CLK1.

The center drawing of FIG. 4B illustrates a condition case2 where the integrator (INT_CIR) 112 has generated the “up” output signal UP. In the condition case2, it is understood that the first selection clock output signal CLK0 and the third selection clock output signal CLK2 which are outputted from the clock selection unit (CLK_SEL) 114 are not buried in the left-hand side jitter component and the right-hand side jitter component, respectively. In the condition case2, it is possible for the clock data recovery circuit (CDR) 11 illustrated in FIG. 3 to recover the reproduction data DATA at a low bit error rate. The condition case2 illustrated in the center drawing of FIG. 4B corresponds to the condition where the fourth clock signal TXCLK3, the fifth clock signal TXCLK4, and the sixth clock signal TXCLK5, selected from the eight-phase clock signals TXCLK0-TXCLK7 are outputted by the clock selection unit (CLK_SEL) 114, as the first selection clock output signal CLK0, the second selection clock output signal CLK1, and the third selection clock output signal CLK2, respectively, and where the rising edge of the receive signal RX from the host 2 is located in timing prior to the rising edge of the first selection clock output signal CLK0.

The right-hand drawing of FIG. 4B illustrates a condition case3 before the integrator (INT_CIR) 112 generates a “down” output signal DN, In the condition case3, it is understood that the third selection clock output signal CLK2 outputted by the clock selection unit (CLK_SEL) 114 is buried in a right-hand side jitter component. In such a condition case3, it is difficult for the clock data recovery circuit (CDR) 11 illustrated in FIG. 3 to recover reproduction data DATA at a low bit error rate. The condition case3 illustrated in the right-hand drawing of FIG. 4B corresponds to the condition where the sixth clock signal TXCLK5, the seventh clock signal TXCLK6, and the eighth clock signal TXCLK7, which are selected from the eight-phase clock signals TXCLK0-TXCLK7, are outputted by the clock selection unit (CLK_SEL) 114, as the first selection clock output signal CLK0, the second selection clock output signal CLK1, and the third selection clock output signal CLK2, respectively, and where the rising edge of the receive signal RX from the host 2 is located in timing between the rising edge of the second selection clock output signal CLK1 and the rising edge of the third selection clock output signal CLK2. When the integrator (INT_CIR) 112 generates a “down” output signal DN in the condition case3, the condition shifts to the condition case2 of the center drawing of FIG. 4B.

In this way, since the clock data recovery circuit (CDR) 11 illustrated in FIG. 3 is all formed with digital circuits, without using an analog circuit which brings about increase of a semiconductor area like an analog filter, it becomes possible to reduce the chip occupied area.

<<Frequency Error Detector>>

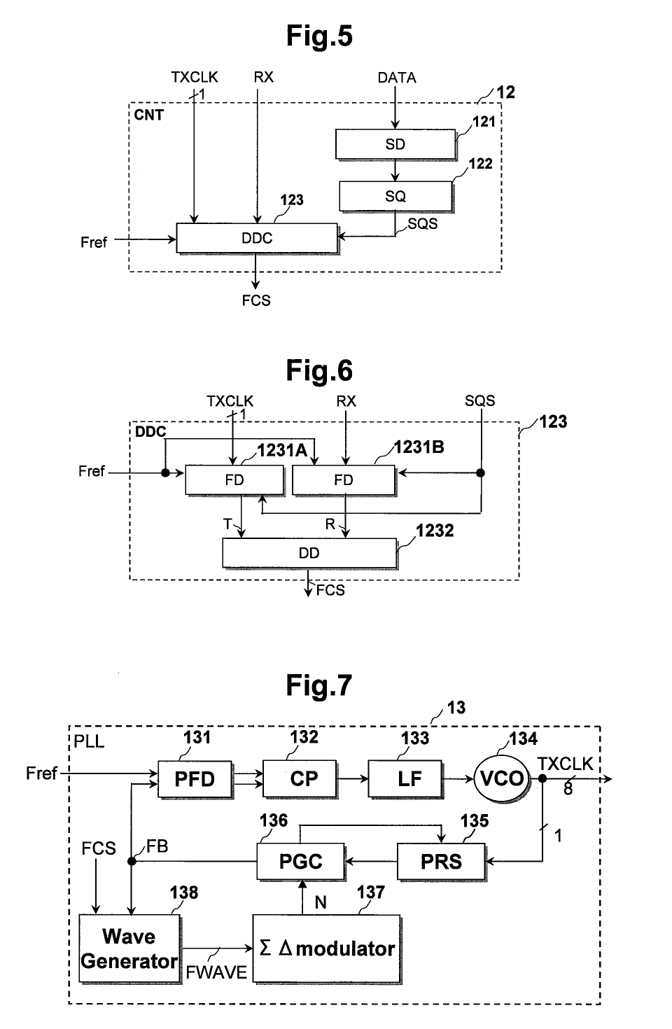

FIG. 5 illustrates a configuration of the frequency error detector (CNT) 12 of the device 1 configured as the transceiver with a transmitting/receiving function illustrated in FIG. 2.

As illustrated in FIG. 5, the frequency error detector (CNT) 12 comprises a signal detector (SD) 121, a sequencer (SQ) 122, and a frequency error detection regulator (DDC) 123.

The signal detector (SD) 121 inputs reproduction data DATA generated by the clock data recovery circuit (CDR) 11 to detect data, and supplies the detection data to the sequencer (SQ) 122. Namely, based on the state of the detection data supplied by the signal detector (SD) 121, it is possible for the sequencer (SQ) 122 to know a state where an error in frequency of the receive signal RX and the transmit clock signal TXCLK becomes conspicuous and prevents normal reproduction of the serial reproduction data DATA and the reproduction clock CLK in the clock data recovery circuit (CDR) 11 illustrated in FIG. 3. For example, in a state where normal reproduction is difficult, the level of the detection data supplied by the signal detector (SD) 121 is held constant. When such a state appears, the sequencer (SQ) 122 outputs a sequence signal SQS as a command which directs a start of an operation of frequency error detection sequence, to the frequency error detection regulator (DDC) 123.

Then, in response to the sequence signal SQS, the frequency error detection regulator (DDC) 123 starts operation which detects an error in frequency of the receive signal RX from the host 2, and the single-phase transmit clock signal TXCLK from the PLL circuit (PLL) 13. When the error in frequency becomes greater than a prescribed value, a high-level frequency control signal FCS is generated by the frequency error detection regulator (DDC) 123. In a state where no sequence signal SQS is supplied by the sequencer (SQ) 122, the frequency error detection regulator (DDC) 123 suspends operation of detecting an error in frequency.

<<Frequency Error Detection Regulator>>

FIG. 6 illustrates a configuration of the frequency error detection regulator (DDC) 123 of the frequency error detector (CNT) 12 illustrated in FIG. 5.

As illustrated in FIG. 6, the frequency error detection regulator (DDC) 123 comprises a first frequency detector (FD) 1231A, a second frequency detector (FD) 1231B, and an error detection circuit (DD) 1232.

Operation of the first frequency detector (FD) 1231A and the second frequency detector (FD) 1231B of the frequency error detection regulator (DDC) 123 is started by the sequence signal SQS supplied by the sequencer (SQ) 122. The first frequency detector (FD) 1231A measures the frequency of the transmit clock signal TXCLK to generate a first number of counts T, by counting pulses of the single-phase transmit clock signal TXCLK supplied by the PLL circuit (PLL) 13 during a count time determined by the reference signal Fref supplied by the reference signal generation source 3. Also, the second frequency detector (FD) 1231B measures the frequency of the receive signal RX to generate a second number of counts R, by counting pulses of the receive signal RX from the host 2 during the count time determined by the reference signal Fref.

The error detection circuit (DD) 1232 detects an error in frequency of the single-phase transmit clock signal TXCLK and the receive signal RX, based on a difference between the first number of counts T supplied by the first frequency detector (FD) 1231A and the second number of counts R supplied by the second frequency detector (FD) 1231B. When the error in frequency becomes larger than a prescribed value, a high-level frequency control signal FCS is generated by the error detection circuit (DD) 1232 of the frequency error detection regulator (DDC) 123, and supplied to the PLL circuit (PLL) 13. Since a pulse width of the high-level frequency control signal FCS is proportional to the difference between the first number of counts T and the second number of counts R, the pulse width of the high-level frequency control signal FCS also increases in proportion to the increase of the error in frequency.

<<PLL Circuit>>

FIG. 7 illustrates a configuration of a PLL circuit (PLL) 13 of the device 1 configured as the transceiver with a transmitting/receiving function illustrated in FIG. 2.

As illustrated in FIG. 7, the PLL circuit (PLL) 13 comprises a phase/frequency comparator (PFD) 131, a charge pump (CP) 132, a loop filter (LF) 133, a voltage-controlled oscillator (VCO) 134, a prescaler (PRS) 135, a programmable counter (PGC) 136, a waveform generator 138, and a ΣΔ-modulator 137. Since the ΣΔ-modulator 137 controls precisely the number of average dividing N of the programmable counter (PGC) 136 configured as a variable divider to a value below a decimal point, especially, in response to the waveform signal FWAVE generated by the waveform generator 138, the PLL circuit (PLL) 13 illustrated in FIG. 7 functions as a fractional PLL circuit as is the case with what is described in Non-patent Document 2 cited above.

The phase/frequency comparator (PFD) 131 compares a phase and frequency of the reference signal Fref of the reference signal generation source 3 and the output signal of the feedback signal FB from the programmable counter (PGC) 136, and supplies a comparison output signal to the charge pump (CP) 132. In response to the comparison output signal of the phase/frequency comparator (PFD) 131, the charge pump (CP) 132 supplies a charge and discharge current to the loop filter (LF) 133, and an output voltage of the loop filter (LF) 133 is determined. The output voltage of the loop filter (LF) 133 is supplied to the voltage-controlled oscillator (VCO) 134 as a frequency control voltage. Accordingly, the frequency of the eight-phase clock signals TXCLK0-TXCLK7 which the voltage-controlled oscillator (VCO) 134 oscillates is controlled by the frequency control voltage outputted by the loop filter (LF) 133. The eight-phase clock signals TXCLK0-TXCLK7 which the voltage-controlled oscillator (VCO) 134 oscillates are supplied to the clock selection unit (CLK_SEL) 114 of the clock data recovery circuit (CDR) 11 illustrated in FIG. 3. On the other hand, a single-phase transmit clock signal TXCLK, which is one phase of the eight-phase clock signals TXCLK0-TXCLK7, is divided by the prescaler (PRS) 135 and the programmable counter (PGC) 136. Since the PLL circuit (PLL) 13 operates so that the phase and frequency of the output signal of the feedback signal FB from the programmable counter (PGC) 136 may be in agreement with the phase and frequency of the reference signal Fref due to the present dividing, the frequency of the eight-phase clock signals TXCLK0-TXCLK7 becomes a product of the number of dividing and the reference signal Fref.

In response to the waveform signal FWAVE generated by the waveform generator 138, the ΣΔ-modulator 137 controls precisely the number of average dividing N of the programmable counter (PGC) 136 configured as a variable divider to a value below a decimal point. Namely, the waveform generator 138 generates a triangular-wave signal FWAVE as a modulating signal, and supplies it to the ΣΔ-modulator 137. When the waveform generator 138 generates the triangular-wave signal FWAVE, the phase of the triangular-wave signal FWAVE is controlled by a frequency control signal FCS which is generated by the error detection circuit (DD) 1232 of the frequency error detection regulator (DDC) 123 illustrated in FIG. 5 and FIG. 6.

<<Voltage-Controlled Oscillator>>

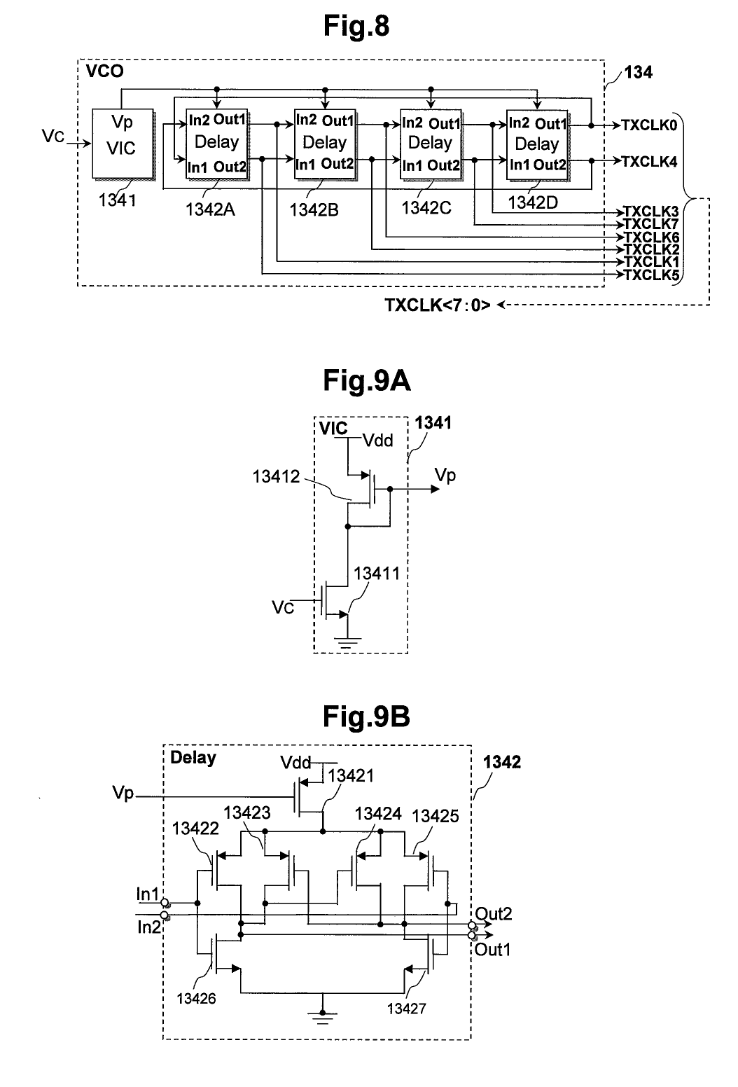

FIG. 8 illustrates a configuration of the voltage-controlled oscillator (VCO) 134 of the PLL circuit (PLL) 13 illustrated in FIG. 7.

As illustrated in FIG. 8, the voltage-controlled oscillator (VCO) 134 comprises a voltage-to-current converter (VIC) 1341 and four-stage delay circuits 1342A, 1342B, 1342C, and 1342D. In response to the frequency control output voltage Vc of the loop filter (LF) 133 of the PLL circuit (PLL) 13 illustrated in FIG. 7, the voltage-to-current converter (VIC) 1341 generates conversion current internally, which is then converted into control voltage Vp also internally. By supplying the control voltage Vp generated by the voltage-controlled oscillator (VCO) 134 to the four-stage delay circuits 1342A-1342D in common, delay time of each delay circuit of the four-stage delay circuits 1342A-1342D is set up. When the control voltage Vp is large, operating current of each delay circuit of the four-stage delay circuits 1342A-1342D becomes large and delay time of each delay circuit becomes small; accordingly, an oscillating frequency of the eight-phase clock signals TXCLK0-TXCLK7 which the voltage-controlled oscillator (VCO) 134 oscillates becomes high. On the contrary, when the control voltage Vp is small, the operating current of each delay circuit of the four-stage delay circuits 1342A-1342D becomes small and the delay time of each delay circuit becomes large; accordingly, an oscillating frequency of the eight-phase clock signals TXCLK0-TXCLK7 which the voltage-controlled oscillator (VCO) 134 oscillates becomes low. In the voltage-controlled oscillator (VCO) 134 illustrated in FIG. 8, from the first output terminal Out1 and the second output terminal Out2 of the first stage delay circuit 1342A, the second phase clock signal TXCLK1 and the sixth phase clock signal TXCLK5 are generated and supplied to the second input terminal In2 and the first input terminal In1 of the second stage delay circuit 1342B. From the first output terminal Out1 and the second output terminal Out2 of the second stage delay circuit 1342B, the seventh phase clock signal TXCLK6 and the third phase clock signal TXCLK2 are generated and supplied to the second input terminal In2 and the first input terminal In1 of the third stage delay circuit 1342C. From the first output terminal Out1 and the second output terminal Out2 of the third stage delay circuit 1342C, the fourth phase clock signal TXCLK3 and the eighth phase clock signal TXCLK7 are generated and supplied to the second input terminal In2 and the first input terminal In1 of the fourth stage delay circuit 1342D. From the first output terminal Out1 and the second output terminal Out2 of the fourth stage delay circuit 1342D, the first phase clock signal TXCLK0 and the fifth phase clock signal TXCLK4 are generated and supplied to the first input terminal In1 and the second input terminal In2 of the first stage delay circuit 1342A.

FIG. 9A illustrates a configuration of the voltage-to-current converter (VIC) 1341 of the voltage-controlled oscillator (VCO) 134 illustrated in FIG. 8. FIG. 9B illustrates a configuration of a delay circuit 1342 which corresponds to each of the four-stage delay circuits 1342A, 1342B, 1342C, and 1342D of the voltage-controlled oscillator (VCO) 134 illustrated in FIG. 8.

As illustrated in FIG. 9A, the voltage-to-current converter (VIC) 1341 comprises an N-channel MOS transistor (abbreviated as NMOS hereinafter) 13411, and a P channel MOS transistor (abbreviated as PMOS hereinafter) 13412. A source of the NMOS 13411 is grounded and conversion current flows through a drain of the NMOS 13411 by supplying the frequency control output voltage Vc generated by the loop filter (LF) 133 to a gate of the NMOS 13411. The diode coupling of the PMOS 13412 is established by coupling a drain and a gate of the PMOS 13412. A source of the PMOS 13412 is coupled to a power supply voltage Vdd, and the control voltage Vp is generated as a source-to-gate voltage drop of the PMOS 13412.

As illustrated in FIG. 9B, the delay circuit 1342 comprises five PMOSs 13421-13425 and two NMOSs 13426 and 13427. Sources of two NMOSs 13426 and 13427 are both grounded, a gate of the NMOS 13426 and a gate of the PMOS 13422 are coupled to a first input terminal In1, and a gate of the NMOS 13427 and a gate of the PMOS 13425 are coupled to a second input terminal In2. A drain of the NMOS 13426 and a drain of the PMOS 13422 are coupled to a first output terminal Out1, and a drain of the NMOS 13427 and a drain of the PMOS 13425 are coupled to a second output terminal Out2. A gate and a drain of the PMOS 13423 are coupled to the second output terminal Out2 and the first output terminal Out1, and a gate and a drain of the PMOS 13424 are coupled to the first output terminal Out1 and the second output terminal Out2. Between the power supply voltage Vdd and sources of four PMOSs 13422-13425, the PMOS 13421 is coupled to form a source-to-drain current path. When the control voltage Vp is large, the drain current of the PMOS 13421 as the operating current of the delay circuit 1342 becomes large, and the delay time of the delay circuit 1342 becomes small.

<<Waveform Generation Unit>>

FIG. 10A illustrates a configuration of the waveform generation unit 138 comprised in the PLL circuit (PLL) 13 illustrated in FIG. 7, and FIG. 10B illustrates the operating waveform of the waveform generation unit 138.

As illustrated in FIG. 10A, the waveform generation unit 138 comprises a waveform generation register (RGS) 1386, an addition unit 1385, a selector 1384, a first data input register 1382, a second data input register 1383, and a divider 1381.

Positive gradient data D is held at the first data input register 1382 and negative gradient data-D is held at the second data input register 1383 for forming gradient of a triangular waveform, so that the waveform generation unit 138 may generate a triangular-wave signal FWAVE. The positive gradient data D and the negative gradient data-D can be generated from the external data D supplied from the outside. The positive gradient data D of the first data input register 1382 and the negative gradient data-D of the second data input register 1383 are supplied to a first input terminal In1 and a second input terminal In2 of the selector 1384, respectively.

The feedback signal FB supplied through the prescaler (PRS) 135 and the programmable counter (PGC) 136 of the PLL circuit (PLL) 13 is divided by the divider 1381, and, as a result, a dividing feedback signal fm is generated and supplied to a selection control terminal of the selector 1384. When the dividing feedback signal fm is at a high level, the positive gradient data D of the first input terminal In1 is selected, and supplied from an output terminal of the selector 1384 to a first input terminal of the addition unit 1385. When the dividing feedback signal fm is at a low level, the negative gradient data-D of the second input terminal In2 is selected, and supplied from the output terminal of the selector 1384 to the first input terminal of the addition unit 1385. The held data of the waveform generation register (RGS) 1386 is supplied from an output terminal of the waveform generation unit 138 to the ΣΔ-modulator 137 as the triangular-wave signal FWAVE, and also supplied to a second input terminal of the addition unit 1385.

On the other hand, the frequency control signal FCS generated by the error detection circuit (DD) 1232 of the frequency error detection regulator (DDC) 123 is supplied to control input terminals of the divider 1381 and the waveform generation register (RGS) 1386. When the frequency control signal FCS is at a high level, the dividing operation of the divider 1381 is stopped and the held data of the waveform generation register (RGS) 1386 is held as it is. On the other hand, when the frequency control signal FCS is at a low level, the dividing operation of the divider 1381 is performed and the waveform generation register (RGS) 1386 stores update information from the addition unit 1385.

FIG. 10B is a waveform chart explaining the operation of the waveform generation unit 138 illustrated in FIG. 10A.

As illustrated in FIG. 10B, in periods T1 and T4 when the dividing feedback signal fm is at a high level, the level of the triangular-wave signal FWAVE increases due to the positive gradient data D of the first data input register 1382. On the other hand, in periods T3 and T5 when the dividing feedback signal fm is at a low level, the level of the triangular-wave signal FWAVE decreases due to the negative gradient data-D of the second data input register 1383. In a period T2 when the frequency control signal FCS is at a high level, the level of the dividing feedback signal fm is held, and the level of the triangular-wave signal FWAVE is also held.

In this way, the ΣΔ-modulator 137 controls precisely the number of average dividing N of the programmable counter (PGC) 136 to a value below a decimal point, in response to the waveform signal FWAVE generated by the waveform generator 138. Therefore, it becomes possible to control the frequency and phase of the eight-phase clock signals TXCLK0-TXCLK7 which are oscillated by the voltage-controlled oscillator (VCO) 134. Through the operation of the waveform generation unit 138, it becomes possible to make the frequency and phase of the eight-phase clock signals TXCLK0-TXCLK7 which are oscillated by the voltage-controlled oscillator (VCO) 134 of the PLL circuit (PLL) 13 approach the frequency and phase of the receive signal RX from the host 2.

<<A Frequency Control Operation of a Transmit Clock>>

The following explains a frequency control operation of a transmit clock TXCLK in a communication system comprising the transceiver according to Embodiment 1 of the present invention, explained in FIG. 2 through FIG. 10B.

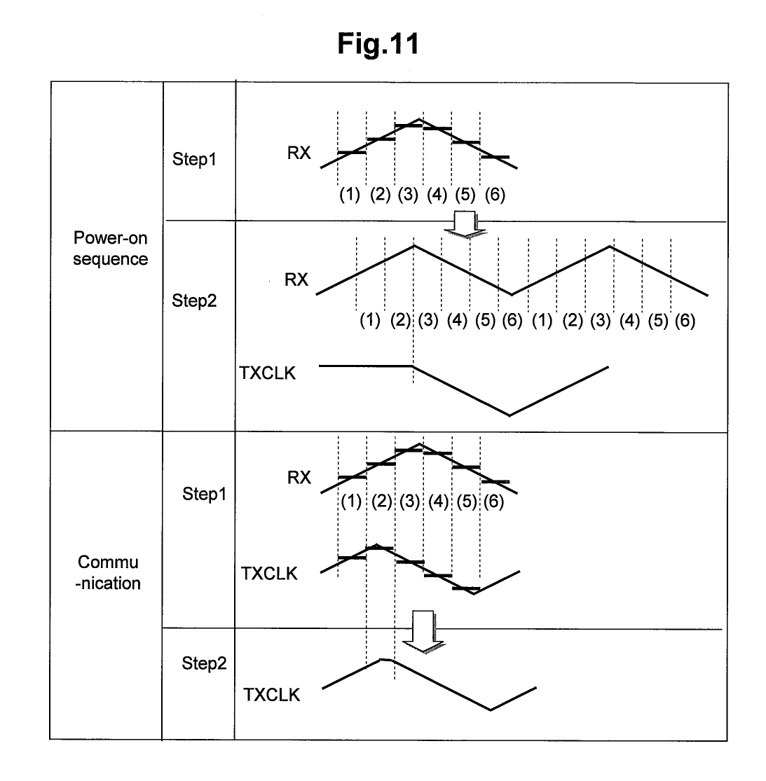

FIG. 11 explains the frequency control operation of the transmit clock TXCLK of the communication system comprising the transceiver according to Embodiment 1 of the present invention, explained in FIG. 2 through FIG. 10B.

The frequency control operation of the transmit clock TXCLK at the time of power-on of a supply voltage (in a power-on sequence) of the transceiver according to Embodiment 1 of the present invention is illustrated in the upper part of FIG. 11.

A first step (Step 1) of the power-on sequence is immediately after the power-on of the supply voltage of the transceiver, and is in a state where it is difficult to perform normal reproduction of the reproduction data DATA and the reproduction clock CLK in the clock data recovery circuit (CDR) 11. Therefore, the sequencer (SQ) 122 outputs a sequence signal SQS as a command which directs a start of an operation of frequency error detection sequence, to the frequency error detection regulator (DDC) 123. Then, the second frequency detector (FD) 1231B of the frequency error detection regulator (DDC) 123 of the frequency error detector (CNT) 12 starts measurement of frequency of the receive signal RX from the host 2, for six divided sections (1)-(6). The second frequency detector (FD) 1231B transmits, to the error detection circuit (DD) 1232 as the second number-of-counts information R, information on the section of the maximum frequency (the third section (3) in the example of FIG. 11) in the measurement results of six sections (1)-(6). On the other hand, immediately after the power-on of the supply voltage of the transceiver, the transmit clock TXCLK has not been oscillated yet by the voltage-controlled oscillator (VCO) 134 of the PLL circuit (PLL) 13. Therefore, the first frequency detector (FD) 1231A transmits non-oscillation information of the transmit clock TXCLK as the first number-of-counts information T, to the error detection circuit (DD) 1232. Then, in response to the first number-of-counts information T and the second number-of-counts information R, the error detection circuit (DD) 1232 generates a frequency control signal FCS which keeps a high level till a section prior to the section of the maximum frequency (the second section (2) in the example of FIG. 11), and supplies the frequency control signal FCS to the waveform generator 138.

Accordingly, at a second step (Step 2) of the power-on sequence, data of the waveform generation register (RGS) 1386 of the waveform generator 138 is maintained at the maximum value till the second section (2), by the frequency control signal FCS which is set high-level till the second section (2). Then, the data of the waveform generation register (RGS) 1386 decreases to the minimum value according to the negative gradient data-D of the second data input register 1383. Subsequently, the data of the waveform generation register (RGS) 1386 increases toward the maximum value according to the positive gradient data D of the first data input register 1382. As a result, the frequency of the transmit clock TXCLK generated by the voltage-controlled oscillator (VCO) 134 of the PLL circuit (PLL) 13 is also maintained at the maximum value till the second section (2), and decreases with a prescribed gradient after that. In this way, with the use of frequency control operation of the transmit clock TXCLK at the time of power-on of the supply voltage of the transceiver (in a power-on sequence), It becomes possible to reduce a difference in frequency of the receive signal RX from the host 2 and the transmit clock TXCLK generated by the PLL circuit (PLL) 13.

A frequency control operation of the transmit clock TXCLK in a communication operation between a host and a device of the transceiver according to Embodiment 1 of the present invention is illustrated in the lower part of FIG. 11.

A difference in frequency of the receive signal RX from the host 2 and the transmit clock TXCLK generated by the PLL circuit (PLL) 13 is reduced immediately after the power-on of the supply voltage, through the frequency control operation of the transmit clock TXCLK in the power-on sequence, explained with reference to the upper part of FIG. 11. However, the difference in frequency of the receive signal RX and the transmit clock TXCLK may increase during a subsequent communication operation between the host and the device of the transceiver.

The frequency error detection regulator (DDC) 123 of the frequency error detector (CNT) 12 detects an error of the frequency of the receive signal RX and the frequency of the transmit clock TXCLK during a communication operation. When the frequency error becomes larger than a prescribed value, the frequency error detection regulator (DDC) 123 generates a frequency control signal FCS having a high level in a pulse period during which the frequency error is corrected.

At a first step (Step1) in the communication operation, the frequency error detection regulator (DDC) 123 of the frequency error detector (CNT) 12 performs measurement of frequency of the receive signal RX from the host 2, and frequency of the transmit clock TXCLK of the PLL circuit (PLL) 13, for six divided sections (1)-(6). When the frequency error becomes larger than a prescribed value during the present measurement, the frequency error detection regulator (DDC) 123 generates a frequency control signal FCS for correcting the frequency error.

Accordingly, in a second step (Step 2) in the communication operation, the frequency of the transmit clock TXCLK generated by the voltage-controlled oscillator (VCO) 134 of the PLL circuit (PLL) 13 is maintained at the maximum value till the end of the second section (2), and decreases with a prescribed gradient after that. In this way, it becomes possible to reduce the difference in frequency of the receive signal RX from the host 2 and the transmit clock TXCLK generated by the PLL circuit (PLL) 13, through the frequency control operation of the transmit clock TXCLK in the communication operation of the transceiver.

### Embodiment 2

### Another Communication System

FIG. 12 illustrates a configuration of a communication system comprising a transceiver according to Embodiment 2 of the present invention.

The communication system according to Embodiment 2 of the present invention illustrated in FIG. 12 is different from the communication system according to Embodiment 1 of the present invention illustrated in FIG. 2 in the point that a frequency error detector (CNT) 12 of a device 1 illustrated in FIG. 12 generates not only a frequency control signal FCS but also a degree-of-modulation adjustment signal MT, and a modulation cycle adjustment signal MN, and supplies them to a PLL circuit (PLL) 13.

<<Another Frequency Error Detector>>

FIG. 14 illustrates a configuration of the frequency error detector (CNT) 12 of the device 1 configured as the transceiver with a transmitting/receiving function according to Embodiment 2 of the present invention 2, illustrated in FIG. 12.

The frequency error detector (CNT) 12 according to Embodiment 2 of the present invention illustrated in FIG. 14 is different from the frequency error detector (CNT) 12 according to Embodiment 1 of the present invention illustrated in FIG. 5 in the following points. That is, when an error of the frequency of the receive signal RX and the frequency of the transmit clock signal TXCLK becomes conspicuous, in response to a sequence signal SQ from a sequencer (SQ) 122, a frequency error detection regulator (DDC) 123 not only generates a frequency control signal FCS, but detects a degree of modulation of the receive signal RX and a degree of modulation of the transmit clock signal TXCLK and generates a degree-of-modulation adjustment signal MT for compensating the error of the degree of modulation. Furthermore, the frequency error detection regulator (DDC) 123 detects a modulation cycle of the receive signal RX and a modulation cycle of the transmit clock signal TXCLK and generates a modulation cycle adjustment signal MN for compensating the error of the modulation cycle.

FIG. 15 illustrate a configuration of the frequency error detection regulator (DDC) 123 of the frequency error detector (CNT) 12 illustrated in FIG. 14.

The first point that the frequency error detection regulator (DDC) 123 according to Embodiment 2 of the present invention illustrated in FIG. 15 is different from the frequency error detection regulator (DDC) 123 according to Embodiment 1 of the present invention illustrated in FIG. 6 is that a first frequency detector (FD) 1231A measures a maximum frequency (UF), an average frequency (AF), and a minimum frequency (DF) of the frequency of the single-phase transmit clock signal TXCLK, and supplies the measurement results to an error detection circuit (DD) 1232. The second point of the difference is that a second frequency detector (FD) 1231B measures a maximum frequency (UF), an average frequency (AF), and a minimum frequency (DF) of the frequency of the receive signal RX, and supplies the measurement results to the error detection circuit (DD) 1232. The third point of the difference is that the error detection circuit (DD) 1232 generates the degree-of-modulation adjustment signal MT and the modulation cycle adjustment signal MN as well as the frequency control signal FCS, in response to the measurement results of the maximum frequency (UF), the average frequency (AF), and the minimum frequency (DF) of the frequency of the single-phase transmit clock signal TXCLK, and also in response to the measurement result of the maximum frequency (UF), the average frequency (AF), and the minimum frequency (DF) of the frequency of the receive signal RX.

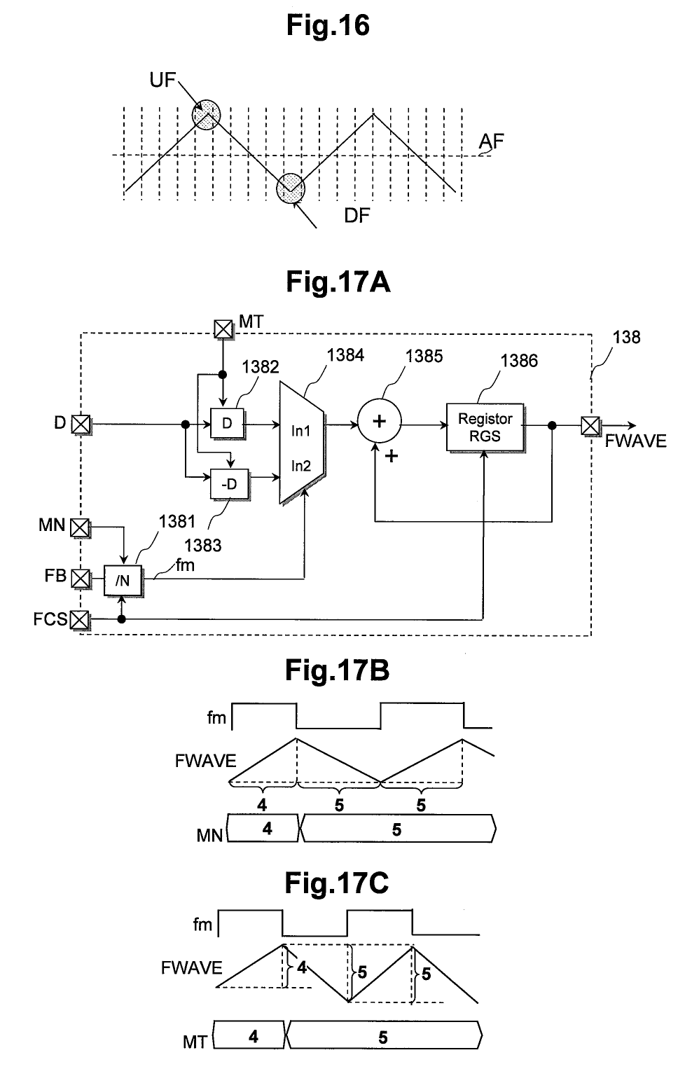

FIG. 16 explains a maximum frequency (UF), an average frequency (AF), and a minimum frequency (DF) of the frequency of the single-phase transmit clock signal TXCLK and the receive signal RX, which are measured by the first and the second frequency detector (FD) 1231A and 1231B of the frequency error detection regulator (DDC) 123 illustrated in FIG. 15.

As illustrated in FIG. 16, the maximum frequency (UF) is the frequency in the section where the frequency is the highest, the minimum frequency (DF) is the frequency in the section where the frequency is the lowest, and the average frequency (AF) is a mean value of the frequency measured for a long time.

<<Another PLL Circuit>>

FIG. 13 illustrates a configuration of a PLL circuit (PLL) 13 of the device 1 configured as a transceiver according to Embodiment 2 of the present invention 2, illustrated in FIG. 12.

The PLL circuit (PLL) 13 according to Embodiment 2 of the present invention illustrated in FIG. 13 is different from the PLL circuit (PLL) 13 according to Embodiment 1 of the present invention illustrated in FIG. 7 in the following points. That is, in the PLL circuit (PLL) 13 illustrated in FIG. 13, the phase of the triangular-wave signal FWAVE generated by the waveform generator 138 is controlled by the frequency control signal FCS generated by the frequency error detector (CNT) 12, and the degree of modulation and the modulation cycle of the triangular-wave signal FWAVE are controlled respectively by the degree-of-modulation adjustment signal MT and the modulation cycle adjustment signal MN, which are generated by the frequency error detector (CNT) 12.

<<Another Waveform Generation Unit>>

FIG. 17A illustrates a configuration of the waveform generation unit 138 of the PLL circuit (PLL) 13 illustrated in FIG. 13.

The waveform generation unit 138 according to Embodiment 2 of the present invention illustrated in FIG. 17A is different from the waveform generation unit 138 according to Embodiment 1 of the present invention illustrated in FIG. 10A in the following points. That is, in the waveform generation unit 138 illustrated in FIG. 17A, the modulation cycle adjustment signal MN generated by the frequency error detector (CNT) 12 is supplied to a divider 1381, and the degree-of-modulation adjustment signal MT generated by the frequency error detector (CNT) 12 is supplied to a first and a second data input registers 1382 and 1383.

FIG. 17B and FIG. 17C illustrate waveform charts explaining operation of the waveform generation unit 138 illustrated in FIG. 17A.

As illustrated in FIG. 17B, since the number of dividing of the divider 1381 can be varied by a value of the modulation cycle adjustment signal MN supplied to the divider 1381, the modulation cycle of the dividing feedback signal fm generated by the divider 1381 becomes variable, and the modulation cycle of the waveform signal FWAVE generated by the waveform generator 138 becomes variable.

As illustrated in FIG. 17C, since the positive and the negative gradient data of the first and the second data input registers 1382 and 1383 can be varied by a value of the degree-of-modulation adjustment signal MT supplied to the first and the second data input registers 1382 and 1383, the degree of modulation (waveform amplitude) of the waveform signal FWAVE generated by the waveform generator 138 becomes variable.

<<Another Frequency Control Operation of the Transmit Clock>>

The following explains a frequency control operation of the transmit clock TXCLK in the communication system comprising the transceiver according to Embodiment 2 of the present invention, explained in FIG. 12 through FIG. 17C.

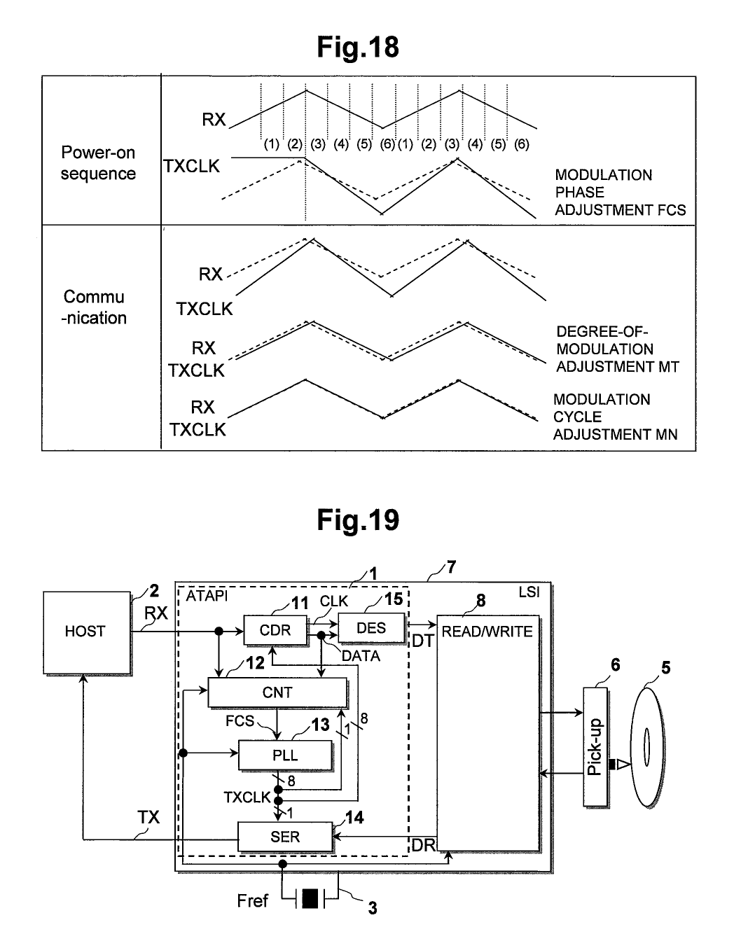

FIG. 18 explains a frequency control operation of the transmit clock TXCLK of the communication system comprising the transceiver according to Embodiment 2 of the present invention, explained in FIG. 12 through FIG. 17C.

The frequency control operation of the transmit clock TXCLK at the time of power-on of a supply voltage (in a power-on sequence) of the transceiver according to Embodiment 2 of the present invention is illustrated in the upper part of FIG. 18.

In the power-on sequence illustrated in FIG. 18, as is the case with the power-on sequence according to Embodiment 1 of the present invention illustrated in FIG. 11, data of the waveform generation register (RGS) 1386 of the waveform generator 138 is maintained at the maximum value till the second section (2), by the frequency control signal FCS which is generated by the frequency error detector (CNT) 12 and which is set high-level till the second section (2), and after that, the data of the waveform generation register (RGS) 1386 decreases to the minimum value according to the negative gradient data. Subsequently, the data of the waveform generation register (RGS) 1386 increases toward the maximum value according to the positive gradient data. As a result, the frequency of the transmit clock TXCLK generated by the voltage-controlled oscillator (VCO) 134 of the PLL circuit (PLL) 13 is also maintained at the maximum value till the second section (2), and decreases with a prescribed gradient after that. Through the frequency control operation of the transmit clock TXCLK of the power-on sequence of the transceiver, it becomes possible to reduce a difference in frequency of the receive signal RX from the host 2 and the transmit clock TXCLK generated by the PLL circuit (PLL) 13.

A frequency control operation of the transmit clock TXCLK in a communication operation between a host and a device of the transceiver according to Embodiment 2 of the present invention is illustrated in the lower part of FIG. 18.

At the time of the communication operation of FIG. 18, as is the time of the communication operation according to Embodiment 1 of the present invention illustrated in FIG. 11, the frequency error detection regulator (DDC) 123 of the frequency error detector (CNT) 12 performs measurement of the frequency of the receive signal RX from the host 2 and the frequency of the transmit clock TXCLK of the PLL circuit (PLL) 13, for six divided sections (1)-(6).

When the frequency error of the frequency of the receive signal RX and the frequency of the transmit clock TXCLK becomes larger than a prescribed value during the communication operation, a modulation cycle adjustment signal MN and a degree-of-modulation adjustment signal MT are generated by the frequency error detector (CNT) 12 so that the frequency error may be compensated. Through the frequency control operation of the transmit clock TXCLK at the time of the communication operation of the transceiver, it becomes possible to reduce a difference in frequency of the receive signal RX from the host 2 and the transmit clock TXCLK generated by the PLL circuit (PLL) 13.

### Embodiment 3

FIG. 19 illustrates a configuration of a communication system with a device as a transceiver comprising a semiconductor integrated circuit according to Embodiment 3 of the present invention.

The communication system illustrated in FIG. 19 comprises an optical disk 5, an optical pickup 6, a semiconductor integrated circuit 7, and a crystal oscillator 3, just like the optical disk device illustrated in FIG. 1. Just like the optical disk device illustrated in FIG. 1, the semiconductor integrated circuit 7 of the communication system illustrated in FIG. 19 comprises an interface unit (ATAPI) 1 coupled with a host computer (HOST) 2 with a serial ATAPI system, and a recording/reproduction unit (READ/WRITE) 8 which performs data writing and data reading of the optical pickup 6.

The interface unit (ATAPI) 1 of the semiconductor integrated circuit 7 illustrated in FIG. 19 comprises a clock data recovery circuit (CDR) 11, a frequency error detector (CNT) 12, a PLL circuit (PLL) 13, a serializer (SER) 14, and a deserializer (DES) 15, with the same configuration as the device 1 according to Embodiment 1 or Embodiment 2 of the present invention described above. Therefore, according to the communication system according to Embodiment 3 of the present invention illustrated in FIG. 19, it becomes possible to reduce a chip area of the semiconductor integrated circuit 7, and also possible to reduce the possibility of malfunction in reproduction of reproduction data and a reproduction clock at the time of receiving a receive signal from the host 2.

As described above, the invention accomplished by the present inventors has been concretely explained based on various embodiments. However, it cannot be overemphasized that the present invention is not restricted to the embodiments, and it can be changed variously in the range which does not deviate from the gist.

For example, the fractional PLL circuit (PLL) 13 comprising the ΣΔ-modulator 137 can use not only a triangular waveform as the waveform signal FWAVE generated by the waveform generator 138, but also other waves such as a sinusoidal wave, in order to configure a spread spectrum clock generator (SSCG) by use of the PLL circuit.

The recording medium 5 for data recording is not limited to rotatable disk recording media, such as HDD/CD/DVD/BD, but can use a mass-capacity semiconductor nonvolatile memory file as well.

What is claimed is:

1. A transceiver comprising:
a clock data recovery circuit;
a deserializer;
a serializer;
a PLL circuit; and
a frequency detector,
wherein the clock data recovery circuit extracts a reproduction clock and reproduction data, in response to a receive signal and a clock signal generated by the PLL circuit,
wherein the deserializer serving as a serial-to-parallel converter generates parallel receive data from the reproduction clock and the reproduction data,
wherein the serializer serving as a parallel-to-serial converter generates a serial transmit signal from parallel transmit data and the clock signal generated by the PLL circuit,
wherein the frequency detector generates a frequency control signal to be supplied to the PLL circuit, by detecting a difference in frequency of the receive signal and the clock signal, and
wherein the PLL circuit controls a cycle of the clock signal so as to reduce the difference in frequency of the receive signal and the clock signal in response to the frequency control signal.

2. The transceiver according to claim 1,
wherein the PLL circuit comprises:
a waveform generator;
a ΣΔ-modulator; and
a variable divider, and
wherein, in response to a waveform signal generated by the waveform generator, the ΣΔ-modulator controls a number of average dividing of the variable divider to a value below a decimal point, and the PLL circuit configures a spread spectrum clock generator.

3. The transceiver according to claim 2,
wherein a phase of the clock signal generated by the PLL circuit is controlled by supplying the frequency control signal generated by the frequency detector to the waveform generator of the PLL circuit.

4. The transceiver according to claim 3,
wherein, by detecting the difference in frequency of the receive signal and the clock signal, the frequency detector generates a modulation cycle adjustment signal and a degree-of-modulation adjustment signal which are supplied to the PLL circuit, and
wherein, in response to the modulation cycle adjustment signal and the degree-of-modulation adjustment signal, the PLL circuit controls the cycle and degree of modulation of the clock signal so as to reduce the difference in frequency of the receive signal and the clock signal.

5. The transceiver according to claim 1,
wherein the clock data recovery circuit comprises:
a phase comparator;
an integrator;
a phase selection unit; and
a clock selection unit,
wherein the clock selection unit is supplied with the multiphase clock signal generated by the PLL circuit and a pointer value generated by the phase selection unit, and generates a plurality of selection clock output signals from the multiphase clock signal, in response to the pointer value,
wherein the phase comparator is supplied with the receive signal and the plural selection clock output signals generated by the clock selection unit, and generates an early phase signal and a late phase signal, in response to relation between a phase of the receive signal and plural phases of the plural selection clock output signals,
wherein the integrator is supplied with the early phase signal and the late phase signal which are generated by the phase comparator, and generates an “up” signal and a “down” signal, and
wherein the clock selection unit is supplied with the “up” signal and the “down” signal which are generated by the integrator, and a value of the pointer value generated by the clock selection unit is set up.

6. The transceiver according to claim 5,
wherein the clock data recovery circuit, the deserializer, the serializer, the PLL circuit, and the frequency detector are formed in a semiconductor integrated circuit.

7. The transceiver according to claim 5,
wherein the waveform signal generated by the waveform generator of the PLL circuit is a triangular-wave signal.

8. An operating method for a transceiver which comprises:
a clock data recovery circuit;
a deserializer;
a serializer;
a PLL circuit; and
a frequency detector,
wherein the clock data recovery circuit extracts a reproduction clock and reproduction data, in response to a receive signal and a clock signal generated by the PLL circuit,
wherein the deserializer serving as a serial-to-parallel converter generates parallel receive data from the reproduction clock and the reproduction data,
wherein the serializer serving as a parallel-to-serial converter generates a serial transmit signal from parallel transmit data and the clock signal generated by the PLL circuit,
wherein the frequency detector generates a frequency control signal to be supplied to the PLL circuit, by detecting a difference in frequency of the receive signal and the clock signal, and
wherein the PLL circuit controls a cycle of the clock signal so as to reduce the difference in frequency of the receive signal and the clock signal in response to the frequency control signal.

9. The operating method for the transceiver according to claim 8,
wherein the PLL circuit comprises:
a waveform generator;
a ΣΔ-modulator; and
a variable divider, and
wherein, in response to a waveform signal generated by the waveform generator, the ΣΔ-modulator controls a number of average dividing of the variable divider to a value below a decimal point, and the PLL circuit configures a spread spectrum clock generator.

10. The operating method for the transceiver according to claim 9,
wherein a phase of the clock signal generated by the PLL circuit is controlled, by supplying the frequency control signal generated by the frequency detector to the waveform generator of the PLL circuit.

11. The operating method for the transceiver according to claim 10,
wherein, by detecting the difference in frequency of the receive signal and the clock signal, the frequency detector generates a modulation cycle adjustment signal and a degree-of-modulation adjustment signal which are supplied to the PLL circuit, and
wherein, in response to the modulation cycle adjustment signal and the degree-of-modulation adjustment signal, the PLL circuit controls the cycle and degree of modulation of the clock signal so as to reduce the difference in frequency of the receive signal and the clock signal.

12. The operating method for the transceiver according to claim 8,
wherein the clock data recovery circuit comprises:
a phase comparator;
an integrator;
a phase selection unit; and
a clock selection unit,
wherein the clock selection unit is supplied with the multiphase clock signal generated by the PLL circuit and a pointer value generated by the phase selection unit, and generates a plurality of selection clock output signals from the multiphase clock signal, in response to the pointer value,
wherein the phase comparator is supplied with the receive signal and the plural selection clock output signals generated by the clock selection unit, and generates an early phase signal and a late phase signal, in response to relation between a phase of the receive signal and plural phases of the plural selection clock output signals,
wherein the integrator is supplied with the early phase signal and the late phase signal which are generated by the phase comparator, and generates an “up” signal and a “down” signal, and
wherein the clock selection unit is supplied with the “up” signal and the “down” signal which are generated by the integrator, and a value of the pointer value generated by the clock selection unit is set up.

13. The operating method for the transceiver according to claim 12,
wherein the clock data recovery circuit, the deserializer, the serializer, the PLL circuit, and the frequency detector are formed in a semiconductor integrated circuit.

14. The operating method for the transceiver according to claim 12,
wherein the waveform signal generated by the waveform generator of the PLL circuit is a triangular-wave signal.
